(19) United States
(12) Patent Application Publication
(10) Pub. No.: US 2026/0353999 A1
(43) Pub. Date: Nov. 5, 2026

(54) OPTICAL DISPLAY APPARATUS

(71) Applicant: HOARDSUN HENGXIN(WUXI) MATERIALS CO., LTD., Wuxi (CN)

(72) Inventors: Dae Hee KWAK, Wuxi (CN); Ye Eun PARK, Wuxi (CN); Byeong Ju BYEON, Wuxi (CN); Gwang Ho SHIN, Wuxi (CN)

(73) Assignee: HOARDSUN HENGXIN(WUXI) MATERIALS CO., LTD., Wuxi (CN)

(21) Appl. No.: 19/659,206

(22) Filed: Apr. 27, 2026

(30) Foreign Application Priority Data
Apr. 30, 2025 (KR) 10-2025-0056978

(51) Int. Cl. H10K 59/80; H10K 59/35

(52) U.S. Cl. CPC H10K 59/8793; H10K 59/35

(57) ABSTRACT

Provided is an optical display apparatus, including a light-emitting element panel, and a polarizing plate positioned on the light-emitting element panel, wherein the polarizing plate includes a second phase difference layer, a first phase difference layer and a polarizer that are positioned sequentially from the light-emitting element panel, wherein in the light-emitting element panel, a red light-emitting material, a green light-emitting material and a blue light-emitting material are arranged asymmetrically, wherein a laminate of the second phase difference layer and the first phase difference layer has a biaxiality coefficient of 0.3 to 0.5 at a wavelength of 550 nm, and wherein when a short side of the light-emitting element panel is set to 0°, a light absorption axis of the polarizer forms an angle of 115 to 125° in a counterclockwise direction with respect to a short side of the light-emitting element panel.

This application claims priority to Korean Patent Application No. 10-2025-0056978, titled “OPTICAL DISPLAY APPARATUS”, filed on Apr. 30, 2025 with the Korean Intellectual Property Office, which is incorporated herein by reference in its entirety.

### FIELD

The present invention relates to an optical display apparatus.

### BACKGROUND

Light-emitting element display apparatuses including organic light-emitting diodes have a problem in that visibility and contrast are reduced due to the reflection of external light. In order to resolve this problem, a polarizing plate including a polarizer and a phase difference film may be used.

The polarizing plate must implement an anti-reflection function to prevent reflected external light from leaking out. Generally, in order to prevent the blackout of polarizing sunglasses, the polarizing plate is positioned such that the light absorption axis of the polarizer is inclined with respect to the panel.

Meanwhile, in glass light-emitting element display apparatuses, the panel generally includes light-emitting elements including a red light-emitting material, a green light-emitting material, and a blue light-emitting material. In order to provide optimal luminous efficiency, it is common to vary the arrangement state of a red light-emitting material, a green light-emitting material and a blue light-emitting material. Typically, the red light-emitting material, the green light-emitting material and the blue light-emitting material can be arranged symmetrically or asymmetrically.

The background art of the present invention is disclosed in Korean Patent Laid-Open Publication No. 10-2013-0103595 and the like.

### SUMMARY

An object of the present invention is to provide an optical display apparatus including a panel in which a red light-emitting material, a green light-emitting material and a blue light-emitting material are arranged asymmetrically, and which has improved reflective color dispersion.

According to an embodiment, provided is an optical display apparatus.

The optical display apparatus includes a light-emitting element panel, and a polarizing plate positioned on the light-emitting element panel, wherein the polarizing plate includes a second phase difference layer, a first phase difference layer and a polarizer that are positioned sequentially from the light-emitting element panel, wherein in the light-emitting element panel, a red light-emitting material, a green light-emitting material and a blue light-emitting material are arranged asymmetrically, wherein a laminate of the second phase difference layer and the first phase difference layer has a biaxiality coefficient of 0.3 to 0.5 at a wavelength of 550 nm, and wherein when a short side of the light-emitting element panel is set to 0° and a long axis thereof is set to 90°, a light absorption axis of the polarizer forms an angle of 115 to 125° in a counterclockwise direction with respect to a short side of the light-emitting element panel.

The present invention includes a panel in which a red light-emitting material, a green light-emitting material and a blue light-emitting material are arranged asymmetrically, and improves the dispersion of reflective colors.

### BRIEF DESCRIPTION OF THE DRAWINGS

FIG. 1 is a cross-sectional diagram of an optical display apparatus according to one embodiment of the present invention.

FIG. 2 is a plan view describing an asymmetric panel.

FIG. 3 is a plan view describing an asymmetric panel.

FIG. 4 is a plan view describing an asymmetric panel.

FIG. 5 is a plan view describing a symmetric panel.

FIG. 6 is a conceptual diagram describing the relationship between the light absorption axes of an asymmetric light-emitting element panel and a polarizer according to examples and comparative examples.

### DETAILED DESCRIPTION OF EMBODIMENTS

The embodiments of the present application will be described in more detail with reference to the attached drawings. However, the technology disclosed in the present application is not limited to the embodiments described herein and may be embodied in other forms. The embodiments introduced herein are provided merely to ensure that the disclosed content is thorough and complete and to ensure that the concept of the present application is sufficiently conveyed to those skilled in the art. In the drawings, the dimensions, such as the width or thickness of the components, are shown slightly enlarged to clearly represent the components of each device, and the dimensions, such as the width or thickness of the components, are not limited to the scope of the present invention. In a plurality of drawings, the same reference numerals refer to substantially identical components.

In the present specification, “upper” and “lower” are defined based on the drawings, and depending on the viewing perspective, “upper” may be changed to “lower” and “lower” to “upper.” In addition, “on” or “above” may include not only the immediate upper portion but also cases where other structures are interposed in the middle. On the other hand, “directly on,” “immediately above” or “directly formed” indicates that no other structure, such as an intermediate, is interposed.

The terms used herein are for describing exemplary embodiments only and are not intended to limit the invention. The singular expression includes the plural expression unless the context clearly indicates otherwise.

In the present specification, the “in-plane phase difference (Re)” is denoted by Formula A below, the “thickness direction phase difference (Rth)” is denoted by Formula B below, and the “degree of biaxiality (NZ)” is denoted by Formula C below:

Re=(nx−ny)×d [Formula A]

Rth=((nx+ny)/2−nz)×d [Formula B]

NZ=(nx−nz)/(nx−ny) [Formula C]
(In Formulas A to C above, nx, ny and nz are the refractive indices of optical elements in the slow axis direction, fast axis direction and thickness direction, respectively, at the measurement wavelength, and d is the thickness of optical elements (unit: nm).)

In Formulas A to C above, the “optical element” may be a first phase difference layer, a second phase difference layer, a protective layer or a laminate of phase difference layers. In Formulas A through C above, the “measurement wavelength” may mean a wavelength of 450 nm, 550 nm or 650 nm.

In the present specification, “(meth)acrylic” means acrylic and/or methacrylic.

When describing numerical ranges in the present specification, “X to Y” means X or more and Y or less (X≤ and ≤Y).

An optical display apparatus according to one embodiment is a light-emitting display apparatus. In one embodiment, the light-emitting element display apparatus may be an organic light-emitting element display apparatus.

The light-emitting element display apparatus essentially includes a light-emitting element panel including a red light-emitting material, a green light-emitting material and a blue light-emitting material. In this case, the red light-emitting material, the green light-emitting material and the blue light-emitting material are arranged asymmetrically in the present invention.

First of all, the asymmetrical arrangement will be explained first.

The asymmetric arrangement is an arrangement in which the individual shapes of the light-emitting elements do not have symmetry in all directions from the center, or all light-emitting elements (B) of the same color adjacent to one light-emitting element (A) do not have the same straight-line distance (A-B) from the light-emitting element (A), or do not have symmetry with respect to the light-emitting element (A).

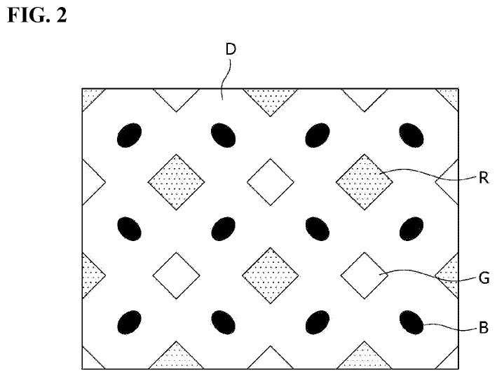

FIG. 2 describes an asymmetric panel according to one embodiment.

Referring to FIG. 2, panel D includes a red light-emitting material R, a green light-emitting material G, and a blue light-emitting material B. The red light-emitting material R and the green light-emitting material G have a square shape. On the other hand, the blue light-emitting material B has an elliptical shape. In this case, therefore, regardless of the position of the red light-emitting material R or the green light-emitting material G in FIG. 2, both sides may be asymmetric with respect to the blue light-emitting material B.

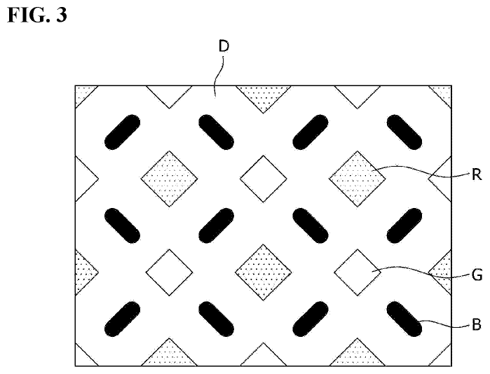

FIG. 3 describes an asymmetric panel according to another embodiment.

Referring to FIG. 3, panel D includes a red light-emitting material R, a green light-emitting material G, and a blue light-emitting material B. The red emitting material R and the green emitting material G have a square shape. On the other hand, the blue emitting material B has an elliptical shape. In this case, therefore, regardless of the position of the red emitting material R or the green emitting material G in FIG. 3, both sides can be asymmetric with respect to the blue emitting material B.

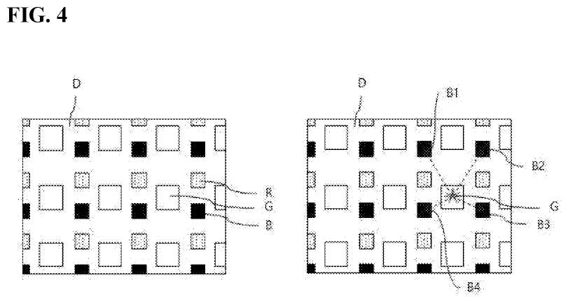

FIG. 4 describes an asymmetric panel according to another embodiment.

Referring to FIG. 4, panel D includes a red light-emitting material R, a green light-emitting material G, and a blue light-emitting material B. All of the red light-emitting material R, the green light-emitting material G and the blue light-emitting material B have a square shape. However, the distance between the green light-emitting material G elements and the adjacent blue light-emitting material B elements B1, B2, B3, B4 is not all the same. In this case, the arrangement of the emitting materials in panel D may be described as an asymmetric arrangement.

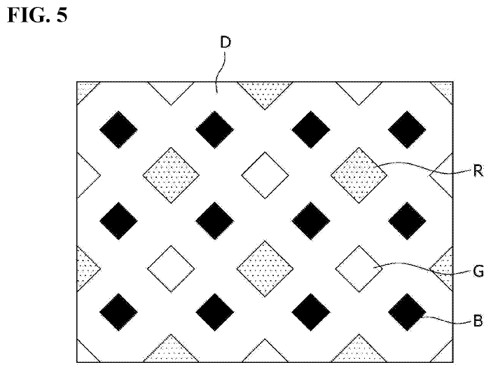

In contrast, FIG. 5 describes a symmetric panel according to one embodiment.

Referring to FIG. 5, panel D includes a red light-emitting material R, a green light-emitting material G, and a blue light-emitting material B. All of the red light-emitting material R, the green light-emitting material G and the blue light-emitting material B have a square shape. In addition, all elements of the same color adjacent to a light-emitting element have the same distance from that light-emitting element. Therefore, the panel D in FIG. 5, in which the red light-emitting material R, the green light-emitting material G and the blue light-emitting material B are arranged, may be described as a symmetric panel.

The red light-emitting material, the green light-emitting material, and the blue light-emitting material may each employ a conventional type known to those skilled in the art.

In addition to the above-described red light-emitting material, the green light-emitting material and the blue light-emitting material, the light-emitting element panel may further include a substrate and the like for protecting the light-emitting materials.

The polarizing plate is laminated on a panel in which the above-described red light-emitting material and the green light-emitting material are arranged asymmetrically to improve the dispersion of reflected colors.

In one embodiment, when the polarizing plate is applied to the light-emitting element display apparatus, the Azimuth Angle Color-change Dimension (AACD) value may be significantly lower, for example, to 2.30 or less. A lower AACD value indicates that the dispersion of reflective luminescence in color coordinates represented by a* and b* reflected colors is reduced, resulting in significantly superior reflective luminescence.

The AACD value may be calculated by the following formula:

AACD=(max(a*)−min(a*))×(max(b*)−min(b*)) [Formula]
(In Formula 5 above,
max (a*) is the largest a* value among the color coordinates of reflected light measured at an incident angle of 0 to 60 degrees and an azimuth angle of 0 to 360 degrees through the DMS 803 of INSTRUMENT STSYEMS,
min (a*) is the smallest a* value among the color coordinates of reflected light measured by the same method,
max (b*) is the largest b* value among the color coordinates of reflected light measured by the same method, and
min (b*) is the smallest b* value among the color coordinates of reflected light measured by the same method.)

The polarizing plate includes a polarizer; and a laminate of phase differences layer laminated on one surface of the polarizer, wherein the laminate of phase difference layers includes a second phase difference layer and a first phase difference layer that are sequentially laminated from the panel.

(i) The laminate of the first phase difference layer and the second phase difference layer has a degree of biaxiality of 0.3 to 0.5 at a wavelength of 550 nm. In addition, (ii) when the short side of the light-emitting element panel is set to 0° and the long side is set to 90°, the light absorption axis of the polarizer forms an angle of 115 to 125° in a counterclockwise direction with respect to the short side of the panel.

When Conditions (i) and (ii) above are satisfied simultaneously, the dispersion of reflected color may be significantly reduced even when including a panel in which the light-emitting materials are arranged asymmetrically.

If the degree of biaxiality of the laminate at a wavelength of 550 nm is less than 0.3, there may be a problem where the dispersion of reflected color on a side surface increases.

If the degree of biaxiality of the laminate at a wavelength of 550 nm is more than 0.5, there may be a problem where the dispersion of reflected color on a side surface increases.

For example, the degree of biaxiality of the laminate at a wavelength of 550 nm may be 0.35 to 0.45.

The degree of biaxiality of the laminate may be implemented by adjusting the degree of biaxiality of the first phase difference layer and/or the second phase difference layer at a wavelength of 550 nm.

When the short side of the panel is set to 0°, if the light absorption axis of the polarizer is less than 115° in a counterclockwise direction, there may be a problem of increased dispersion of the reflected color.

When the short side of the panel is set to 0°, if the light absorption axis of the polarizer is greater than 125° in a counterclockwise direction, there may be a problem of increased dispersion of the reflected color.

For example, when the short side of the panel is set to 0°, the light absorption axis of the polarizer may be 118° to 123° in a counterclockwise direction.

Here, the light absorption axis of the polarizer is a machine direction of the polarizer. The angle may be implemented by adjusting a lamination angle when laminating the polarizing plate on the light-emitting element panel.

### First Phase Difference Layer

The first phase difference layer is an inverse wavelength dispersible phase difference layer, and satisfies Formulas 1 and 2 below:

0.81≤Re(450)/Re(550)≤0.88 [Formula 1]

1.01≤Re(650)/Re(550)≤1.10 [Formula 2]
(In Formulas 1 and 2 above,
Re (450), Re (550) and Re (650) are the in-plane phase differences at wavelengths of 450 nm, 550 nm and 650 nm of the first phase difference layer, respectively).

In one embodiment, Re (450)/Re (550) of Formula 1 above may be 0.83 to 0.88, and Re (650)/Re (550) of Formula 2 above may be 1.01 to 1.08.

In one embodiment, the first phase difference layer is a positive A layer (nx>ny=nz), and it may be combined with a second phase difference layer, which is a positive C layer, to facilitate the improvement of reflective light when applied to a display apparatus including a light-emitting element.

The first phase difference layer may have Re of 100 to 160 nm at a wavelength of 550 nm. Within the above range, changes in reflective light may be minimized when combined with the second phase difference layer. Preferably, Re may be 120 to 150 nm, 130 to 145 nm, and more preferably 135 to 145 nm.

The first phase difference layer may have Re of 100 to 160 nm at a wavelength of 450 nm. Within the above range, changes in reflective visual perception may be minimized when combined with the second phase difference layer. Preferably, Re may be 110 to 150 nm, 114 to 145 nm, and more preferably 115 to 130 nm.

The first phase difference layer may have Re of 100 to 160 nm at a wavelength of 650 nm. Within the above range, changes in reflective visual perception may be minimized when combined with the second phase difference layer. Preferably, Re may be 130 to 160 nm, and more preferably 135 to 155 nm.

The first phase difference layer may have Rth of 50 to 85 nm at a wavelength of 550 nm, preferably 50 to 80 nm, and more preferably 55 to 70 nm. Within the above ranges, the Re range of the first phase difference layer may be easily reached.

The first phase difference layer may have NZ of 0.8 to 1.1, preferably 0.85 to 1.05, and more preferably 0.9 to 1.02 at a wavelength of 550 nm. Within the above ranges, the Re range of the first phase difference layer may be easily reached.

The first phase difference layer may have a total light transmittance of 90% or more, for example, 90% to 100%, and a haze of 0.3% or less, for example, 0% to 0.3% or 0.1% to 0.3%. Within the above ranges, it may be used in a laminate of phase difference layers.

The first phase difference layer may have a thickness of 10 μm or less, for example, more than 0 μm and 10 μm or less, or 1 to 5 μm. Within the above ranges, the wavelength dispersion described above may be easily reached.

The first phase difference layer may be a non-liquid crystal film, but preferably may be a liquid crystal layer. The liquid crystal layer may be configured to easily achieve the wavelength dispersion described above.

The liquid crystal layer may be formed from a conventional liquid crystal material known to those skilled in the art. For example, the liquid crystal layer may include a liquid crystal compound such as a nematic liquid crystal.

The phase difference of the first phase difference layer may be implemented by controlling the type of liquid crystal compound, the orientation angle of the liquid crystal compound, and the thickness of the liquid crystal layer when forming the liquid crystal layer.

The first phase difference layer has a slow axis and a fast axis in the in-plane direction, and the slow axis of the first phase difference layer has a relationship of substantially 45 degrees relative to the light absorption axis of the polarizer.

For example, when the light absorption axis of the polarizer is set to 0°, the slow axis of the first phase difference layer is −47° to −43° or 43° to 47°. Preferably, it may be −46° to −44° or 44° to 46°, and more preferably −45.5° to −44.5° or 44.5° to 45.5°. Within the above ranges, it may be easy to lower the AACD value when applied to a display apparatus.

### Second Phase Difference Layer

The second phase difference layer is a positive C layer (nz>nx=ny), and it may be combined with the first phase difference layer to minimize changes in reflective visual perception.

The second phase difference layer may have Rth of −100 to −50 nm at a wavelength of 550 nm. Within the above range, color change may be minimized. Preferably, the second phase difference layer may have Rth of −90 to −60 nm at a wavelength of 550 nm, and more preferably −85 to −65 nm.

The second phase difference layer may have Re of 10 nm or less at a wavelength of 550 nm, for example, 0 to 10 nm. Within the above range, the range of Rth described above may be easily reached.

The second phase difference layer may have a total light transmittance of 90% or more, for example, 90% to 100%, and a haze of 1% or less, for example, 0% to 0.8% or 0.1% to 0.7%. Within the above ranges, it may be used in a laminate of phase difference layers.

The second phase difference layer may have a thickness of 10 μm or less, for example, more than 0 μm and 10 μm or less, and for example, 1 to 5 μm. Within the above range, the wavelength dispersion described above may be easily achieved.

The second phase difference layer has a lower refractive index than the first phase difference layer, and the second phase difference layer may have a refractive index of 1 to 2, preferably 1.4 to 1.6, and more preferably 1.5 to 1.6.

The second phase difference layer may be formed from a material different from the first phase difference layer, and it may be formed of a material having different birefringences, being hydrophobic, and having a negative intrinsic birefringence.

The second phase difference layer may be a non-liquid crystal layer, but preferably may be a liquid crystal layer. The liquid crystal layer may be easily achieved to the wavelength dispersion described above.

The liquid crystal layer may be formed from a conventional liquid crystal material known to those skilled in the art. For example, the liquid crystal layer may include a liquid crystal compound such as a nematic liquid crystal.

The phase difference of the second phase difference layer may be implemented by controlling the type of liquid crystal compound, the orientation angle of the liquid crystal compound, the thickness of the liquid crystal layer and the like, when forming the liquid crystal layer.

The second phase difference layer may further include conventional additives known to those skilled in the art. The additives may include, but are not limited to, pigments, antioxidants, antistatic agents, thermal stabilizers and the like.

### Laminate of Phase Difference Layers of First Phase Difference Layer and Second Phase Difference Layer

The laminate of phase difference layers is laminated between a polarizer and a panel for an optical display apparatus.

The laminate of phase difference layers has a first phase difference layer and a second phase difference layer that are sequentially laminated from the polarizer.

The laminate of phase difference layers has a degree of biaxiality of 0.1 to 0.5 at a wavelength of 450 nm and a degree of biaxiality of 0.3 to 0.75 at a wavelength of 650 nm.

The laminate of phase difference layers satisfies the above-described degree of biaxiality at wavelengths of 450 nm, 550 nm, and 650 nm, respectively. In this case, the AACD value may be significantly reduced when the first phase difference layer satisfies Formulas 1 and 2 above, and includes the second phase difference layer. In particular, the AACD value may be significantly reduced when the polarizing plate is applied to a display apparatus.

In one embodiment, the degree of biaxiality of the laminate of phase difference layers is 0.3 to 0.5 and 0.4 to 0.5 at a wavelength of 450 nm, 0.35 to 0.5 and 0.35 to 0.45 at a wavelength of 550 nm, and 0.65 to 0.75 and 0.6 to 0.7 at a wavelength of 650 nm.

The degree of biaxiality of the laminate of phase difference layers at wavelengths of 450 nm, 550 nm and 650 nm may be implemented by adjusting the phase difference between the first phase difference layer and the second phase difference layer.

The laminate of phase difference layers may have an in-plane phase difference of 100 to 160 nm, for example, 110 to 140 nm, and a thickness direction phase difference of −40 to 20 nm, for example, −15 to 10 nm, at a wavelength of 450 nm. Within the above ranges, the above-described degree of biaxiality may be easily achieved.

The laminate of phase difference layers may have an in-plane phase difference of 100 to 160 nm, for example, 120 to 150 nm, and a thickness direction phase difference of −10 to 40 nm, for example, 5 to 30 nm, at a wavelength of 550 nm. Within the above ranges, the above-described degree of biaxiality may be easily achieved.

The laminate of phase difference layers may have an in-plane phase difference of 100 to 160 nm, for example, 110 to 140 nm, and a thickness direction phase difference of −5 to 45 nm, for example, 10 to 35 nm at a wavelength of 650 nm. Within the above ranges, the above-described degree of biaxiality may be easily achieved.

The laminate of phase difference layers may have a thickness of 20 μm or less, preferably 1 to 20 μm, and more preferably 5 to 10 μm. Within the above ranges, it may be used in a polarizing plate.

### Polarizer

A polarizer may contribute to lowering the reflection color and reflectance across the entire viewing angle by linearly polarizing external light or light incident from the phase difference laminate.

The polarizer may have a degree of polarization of 99% or more and a single light transmittance (Ts) of 42% or more. By simultaneously satisfying the degree of polarization and single light transmittance, the reflectance may be significantly lowered when the polarizer is laminated onto a phase difference laminate. The “single light transmittance” refers to a single light transmittance (Ts) measured in the visible light region, for example, at a wavelength of 400 nm to 700 nm, and may be measured by conventional methods known to those skilled in the art. The “degree of polarization” may be measured by conventional methods known to those skilled in the art. Specifically, the degree of polarization may be 99% to 99.9999%, and the light transmittance may be 42% to 50%.

The light absorption axis of the polarizer may be the stretching direction, for example, the machine direction (MD) of the polarizer, when manufacturing the polarizer from a polyvinyl alcohol-based film. The polarizer may include a polyvinyl alcohol-based polarizer manufactured by uniaxially stretching a polyvinyl alcohol-based film. In one embodiment, the polarizer may be manufactured by dyeing, stretching, crosslinking and color correction processes of a polyvinyl alcohol-based film. A polarizer having the above-described degree of polarization and light transmittance simultaneously may be achieved by appropriately changing conditions in the above-described dyeing, stretching, crosslinking, and color correction processes. The polarizer may have a thickness of 5 μm to 40 μm. Within the above range, it may be used in a polarizing plate.

The polarizing plate may include an adhesive layer between the first phase difference layer and the second phase difference layer.

### Adhesive Layer

The adhesive layer may be used to laminate the first phase difference layer and the second phase difference layer together.

The adhesive layer may be formed from a conventional adhesive composition known to those skilled in the art. For example, the adhesive layer may be formed from one or more compositions selected from photocurable adhesives and water-based adhesives. Preferably, the adhesive layer may be formed from a photocurable adhesive to provide a thin polarizing plate.

The adhesive layer may have a thickness of 10 μm or less, for example, 1 to 5 μm. Within the above range, it may be used in a polarizing plate.

The polarizing plate may include one or more additional protective layers as described below, in addition to the laminate of phase difference layers.

In one embodiment, a protective layer may be laminated on the other surface of the polarizer.

### Protective Layer

A protective layer may be laminated on the upper surface of a polarizer to protect the polarizer. By protecting the polarizer, the protective layer may increase the reliability of the polarizing plate and increase the mechanical strength of the polarizing plate. If the mechanical properties of the polarizing plate can be secured even without the protective layer, the protective layer may be omitted. One or more protective layers may be laminated on the upper surface of the polarizer.

The protective layer may include one or more of an optically transparent protective film or a protective coating layer. The protective film may include, but is not limited to, a film formed from one or more of a cellulose ester-based resin including triacetylcellulose (TAC) and the like, a cyclic polyolefin-based resin including amorphous cyclic polyolefin (COP) and the like, a polycarbonate-based resin; a polyester-based resin including polyethylene terephthalate (PET) and the like, a polyethersulfone-based resin, a polysulfone-based resin; a polyamide-based resin, a polyimide-based resin, an acyclic-polyolefin-based resin, a poly(meth)acrylate resin including polymethyl methacrylate resin and the like, a polyvinyl alcohol-based resin, a polyvinyl chloride resin and a polyvinylidene chloride resin.

The protective coating layer may be formed from an active energy beam curable resin composition including an active energy beam curable compound and a polymerization initiator. The active energy beam curable compound may include one or more of a cationic polymerizable curable compound, a radical polymerizable curable compound, a urethane resin and a silicone-based resin.

The protective layer may be a phase-less film or may have an in-plane phase difference within a predetermined range. For example, the protective layer may have an in-plane phase difference of less than 5,000 nm, or 5,000 nm or more, 120 to 160 nm, or 5 nm to 0 nm at a wavelength of 550 nm. Within the above ranges, the polarizing plate may be protected without affecting the effects of a phase difference film laminate.

The thickness of the protective layer may be 10 μm or less, 5 μm to 300 μm, 5 μm or less or 5 μm to 200 μm. Within the above ranges, it may be used on a polarizing plate.

A functional coating layer may be additionally formed on the upper surface of the protective layer. The functional coating layer may include, but is not limited to, one or more of a hard coating layer, an anti-fingerprint layer, an anti-reflective layer, an anti-glare layer, a low-reflection layer and an ultra-low-reflection layer.

One or more of a protective layer, an adhesive layer and an adhesive layer may be further laminated between one or more of between the polarizer and the laminate of phase difference layers, and on the lower surface of the laminate of phase difference layers. The protective layer is substantially the same as described above.

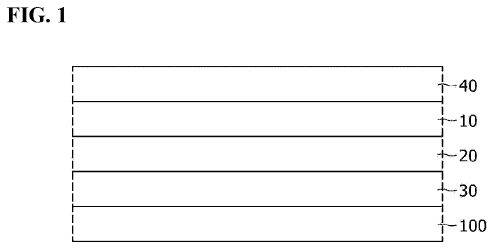

FIG. 1 is a cross-sectional diagram of an optical display apparatus according to one embodiment of the present invention.

The optical display apparatus includes a light-emitting element panel 100 and a polarizing plate positioned on the light-emitting element panel 100, and the polarizing plate may include a second phase difference layer 30, a first phase difference layer 20, a polarizer 10 and a protective layer 40 that are formed sequentially from the light-emitting element panel 100.

Hereafter, the constitutions and operations of the present invention will be explained in more detail through preferred examples of the present invention. However, this is presented as a preferred example of the present invention and should not be interpreted in any way as limiting the present invention.

### Example 1

A polyvinyl alcohol-based film (Kuraray, Japan; thickness before stretching: 60 μm) was dyed in an aqueous iodine solution at 55 °C and stretched 6 times along the MD axis of the film to produce a polarizer (light transmittance: 44%, thickness: 7 μm).

A triacetylcellulose film (thickness: 29 μm) having a hard coating layer formed as a protective layer was laminated onto the upper surface of the polarizer produced above.

An inverse wavelength dispersible phase difference layer (positive A layer, inverse wavelength dispersible, Re: 142 nm, Rth: 62 nm, NZ: 0.94 at wavelength 550 nm, liquid crystal layer, thickness: 2.5 μm) and a positive C layer (Rth: −80 nm at wavelength 550 nm, liquid crystal layer, thickness: 3.5 μm) were bonded together with an adhesive layer (thickness: 2.5 μm) using a photocurable adhesive (including epoxy resin). The laminate of the inverse wavelength dispersible phase difference layer and the positive C layer had a degree of biaxiality of 0.37 at a wavelength of 550 nm.

The inverse wavelength dispersible phase difference layer was bonded to a lower surface of the above-produced polarizer with an adhesive layer (thickness: 2.5 μm) using a photocurable adhesive (including epoxy resin), thereby manufacturing a polarizing plate in which a triacetylcellulose film formed with a hard-coating layer—a polarizer—an adhesive layer—an inverse wavelength dispersible phase difference layer (the slow axis formed 45° with respect to the absorption axis of the polarizer)—an adhesive layer—a positive C layer were laminated in this order.

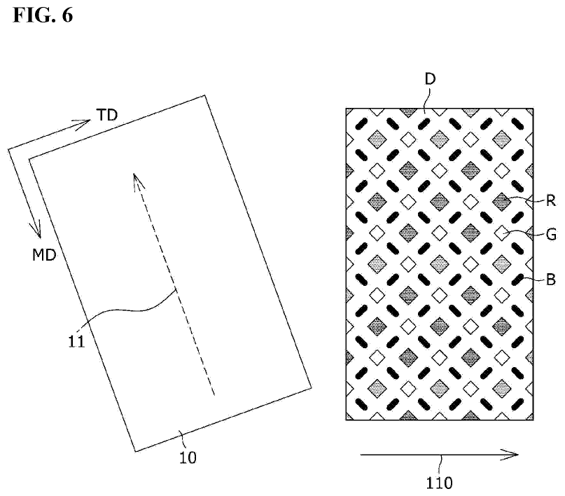

The polarizing plate was laminated on a light-emitting element panel having the arrangement shown in FIG. 6. Referring to FIG. 6, a red light-emitting material R, a green light-emitting material G and a blue light-emitting material B are arranged asymmetrically on panel D. With respect to reference 110 (the short side of the light-emitting element panel), the light absorption axis 11 of the polarizer 10 forms 120° in a counterclockwise direction.

### Example 2

An optical display apparatus was manufactured in the same manner as in Example 1, except that the angle formed by the light absorption axis 11 of polarizer 10 with respect to the reference 110 in Example 1 was changed to 115°.

### Example 3

An optical display apparatus was manufactured in the same manner as in Example 1, except that the angle formed by the light absorption axis 11 of polarizer 10 with respect to the reference 110 in Example 1 was changed to 125°.

### Example 4

An optical display apparatus was manufactured in the same manner as in Example 1, except that the phase difference characteristics of the inverse wavelength dispersible phase difference layer and the positive C layer were changed such that the degree of biaxiality of the laminate of the inverse wavelength dispersible phase difference layer and the positive C layer was changed to 0.3 at a wavelength of 550 nm.

### Example 5

An optical display apparatus was manufactured in the same manner as in Example 1, except that the phase difference characteristics of the inverse wavelength dispersible phase difference layer and the positive C layer in Example 1 were changed such that the degree of biaxiality of the laminate of the reverse wavelength dispersible phase difference layer and the positive C layer was changed to 0.5 at a wavelength of 550 nm.

### Comparative Examples 1 to 5

Optical display apparatuses were manufactured in the same manner as in Example 1, except that the angle formed by the light absorption axis 11 of the polarizer 10 with respect to the reference 110 in Example 1 was changed as shown in Table 1 below.

The phase difference of each of the laminate of phase difference layers, the first phase difference layer, and the second phase difference layer was measured using Axoscan (Axometry).

When the above-manufactured polarizing plate was attached to a light-emitting panel of an OLED display apparatus and driven, the AACD value was calculated according to the above formula.

TABLE 1

| | | Example | | | | | Comparative Example | | | | |
|---|---|---|---|---|---|---|---|---|---|---|---|
| | | 1 | 2 | 3 | 4 | 5 | 1 | 2 | 3 | 4 | 5 |
| NZ of | @550 nm | 0.4 | 0.4 | 0.4 | 0.3 | 0.5 | 0.4 | 0.4 | 0.4 | 0.4 | 0.4 |
| laminate | @450 nm | 0.3 | 0.3 | 0.3 | 0.1 | 0.4 | 0.3 | 0.3 | 0.3 | 0.3 | 0.3 |
| | @650 nm | 0.4 | 0.4 | 0.4 | 0.3 | 0.5 | 0.4 | 0.4 | 0.4 | 0.4 | 0.4 |

| | | | | | | | | | | |
|---|---|---|---|---|---|---|---|---|---|---|
| Angle | 120 | 115 | 125 | 120 | 120 | 0 | 45 | 90 | 105 | 135 |
| Panel | Asym- | Asym- | Asym- | Asym- | Asym- | Asym- | Asym- | Asym- | Asym- | Asym- |
| | metry | metry | metry | metry | metry | metry | metry | metry | metry | metry |
| AACD | 2.25 | 2.29 | 2.28 | 2.30 | 2.30 | 3.46 | 2.37 | 2.67 | 2.68 | 2.81 |

As shown in Table 1 above, the optical display apparatuses of the examples had AACD values of 2.30 or less, indicating that the reflection color dispersion was improved, even though they included the panel in which a red light-emitting material, a green light-emitting material and a blue light-emitting material were arranged asymmetrically.

However, as shown in Table 1 above, the optical display apparatuses of Comparative Examples 1 to 5 had AACD values of more than 2.30, resulting in a weak effect on reflection color dispersion compared to the examples.

Simple variations or modifications of the present invention can be easily implemented by those skilled in the art, and all such variations or modifications are considered to be within the scope of the present invention.

1. An optical display apparatus, comprising: a light-emitting element panel, and a polarizing plate positioned on the light-emitting element panel,
wherein the polarizing plate comprises a second phase difference layer, a first phase difference layer and a polarizer that are positioned sequentially from the light-emitting element panel,
wherein in the light-emitting element panel, a red light-emitting material, a green light-emitting material and a blue light-emitting material are arranged asymmetrically,
wherein a laminate of the second phase difference layer and the first phase difference layer has a biaxiality coefficient of 0.3 to 0.5 at a wavelength of 550 nm, and
wherein when a short side of the light-emitting element panel is set to 0°, a light absorption axis of the polarizer forms an angle of 115 to 125° in a counterclockwise direction with respect to a short side of the light-emitting element panel.

2. The optical display apparatus of claim 1, wherein the first phase difference layer is inverse wavelength dispersible.

3. The optical display apparatus of claim 1, wherein the first phase difference layer has a degree of biaxiality of 0.8 to 1.1 at a wavelength of 550 nm.

4. The optical display apparatus of claim 1, wherein the first phase difference layer has a thickness direction phase difference of 50 to 85 nm at a wavelength of 550 nm.

5. The optical display apparatus of claim 1, wherein the first phase difference layer is a positive A layer.

6. The optical display apparatus of claim 1, wherein the second phase difference layer is a positive C layer.

7. The optical display apparatus of claim 1, wherein the laminate of phase difference layers has an in-plane phase difference of 100 to 160 nm at a wavelength of 550 nm and a thickness direction phase difference of −10 to 40 nm at a wavelength of 550 nm.

8. The optical display apparatus of claim 1, wherein the first phase difference layer is a liquid crystal layer, and the second phase layer is a liquid crystal layer.

9. The optical display apparatus of claim 1, wherein when a light absorption axis of the polarizer is set to 0°, a slow axis of the first phase difference layer is −47° to −43° or 43° to 47°.

10. The optical display apparatus of claim 1, wherein the laminate of the first phase difference layer and the second phase difference layer has a degree of biaxiality of 0.3 to 0.5 at a wavelength of 450 nm and a degree of biaxiality of 0.55 to 0.75 at a wavelength of 650 nm.
